(19) United States
(12) Patent Application Publication
(10) Pub. No.: US 2025/0022811 A1
(43) Pub. Date: Jan. 16, 2025

(54) SEMICONDUCTOR PACKAGE

(71) Applicant: Samsung Electronics Co., Ltd., Suwon-si (KR)

(72) Inventors: Myungyeon Kim, Suwon-si (KR); Mihyae Park, Suwon-si (KR); Minseob Kim, Suwon-si (KR); Woojung Park, Suwon-si (KR)

(21) Appl. No.: 18/432,152

(22) Filed: Feb. 5, 2024

(30) Foreign Application Priority Data
Jul. 12, 2023 (KR) 10-2023-0090370

(51) Int. Cl. H01L 23/00; H01L 23/373; H01L 23/538; H01L 25/065

(52) U.S. Cl. CPC H01L 23/562; H01L 23/3736; H01L 23/5385; H01L 25/0655; H01L 24/16; H01L 24/32; H01L 24/73; H01L 2224/16227; H01L 2224/32225; H01L 2224/73204

(57) ABSTRACT

A semiconductor package includes a substrate including a first interconnection, an interposer disposed on the substrate, the interposer including a second interconnection electrically connected to the first interconnection, first and second semiconductor chips disposed on the interposer, the first and second semiconductor chips electrically connected to each other through the second interconnection, and a stiffener disposed on the substrate to be spaced apart from the interposer, the stiffener including a body portion having a cavity, and a porous thermally conductive portion within the cavity. The body portion includes a first material having a first coefficient of thermal expansion. The porous thermally conductive portion includes a second material having a second coefficient of thermal expansion, greater than the first coefficient of thermal expansion.

### CROSS-REFERENCE TO RELATED APPLICATION(S)

This application claims priority under 35 U.S.C § 119 to Korean Patent Application No. 10-2023-0090370 filed on Jul. 12, 2023 in the Korean Intellectual Property Office, the disclosure of which is incorporated herein by reference in its entirety.

### BACKGROUND

The present inventive concept relates to a semiconductor package.

In accordance with the trend for high-performance electronic products, semiconductor packaging technology in which a high-performance semiconductor chip is mounted on a large-area substrate has been developed. In this case, warpage may occur due to a difference in coefficients of thermal expansion between a substrate and a semiconductor chip. It is important to develop a technology for compensating for a difference in coefficients of thermal expansion between different materials and controlling warpage.

### SUMMARY

An aspect of the present inventive concept is to provide a semiconductor package having improved reliability.

According to an aspect of the present inventive concept, a semiconductor package includes a substrate including a first interconnection, an interposer disposed on the substrate, the interposer including a second interconnection electrically connected to the first interconnection, first and second semiconductor chips disposed on the interposer, the first and second semiconductor chips electrically connected to each other through the second interconnection, and a stiffener disposed on the substrate to be spaced apart from the interposer, the stiffener including a body portion having a cavity, and a porous thermally conductive portion within the cavity. The body portion may include a first material having a first coefficient of thermal expansion. The porous thermally conductive portion may include a second material having a second coefficient of thermal expansion, greater than the first coefficient of thermal expansion.

According to another aspect of the present inventive concept, a semiconductor package includes a substrate, at least one semiconductor chip disposed on the substrate, and a stiffener disposed on the substrate, the stiffener including a body portion having a cavity, and a porous thermally conductive portion within the cavity. The porous thermally conductive portion may include a porous molded body or a mesh-type plate. A tensile strength of the body portion may be greater than a tensile strength of the porous thermally conductive portion. A thermal conductivity of the porous thermally conductive portion may be greater than a thermal conductivity of the body portion.

According to another aspect of the present inventive concept, a semiconductor package includes a substrate, an interposer disposed on the substrate, at least one semiconductor chip disposed on the interposer, and a stiffener disposed on the substrate, the stiffener including a body portion having a cavity and a thermally conductive portion within the cavity. The body portion may include a lower body providing the cavity and an upper body covering the lower body and the thermally conductive portion. A first thermal conductivity of the body portion may be less than a second thermal conductivity of the thermally conductive portion.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a plan view illustrating a semiconductor package according to an example embodiment, and FIG. 1B is a cross-sectional view taken along line I-I′ of FIG. 1A;

FIGS. 2A and 2B are perspective views of stiffeners applicable to example embodiments;

FIGS. 3A to 3C are perspective views of stiffeners according to some example embodiments.

FIG. 4A is a plan view of a semiconductor package according to an example embodiment, and FIG. 4B is a cross-sectional view taken along line II-II′ of FIG. 4A;

FIG. 5A is a plan view of a semiconductor package according to an example embodiment, FIG. 5B is a cross-sectional view taken along line III-III′ of FIG. 5A, and FIG. 5C is a cross-sectional view of an interposer package according to an example embodiment; and

FIG. 6 is a cross-sectional view of a semiconductor package according to an example embodiment of the present inventive concept.

### DETAILED DESCRIPTION

Hereinafter, preferred example embodiments of the present inventive concept will be described below with reference to the accompanying drawings. Unless otherwise specified, in the present specification, terms such as “upper,” “upper portion,” “upper surface,” “lower,” “lower portion,” “lower surface,” and “side surface” are based on the drawings, and may vary depending on a direction in which an element or component is actually arranged.

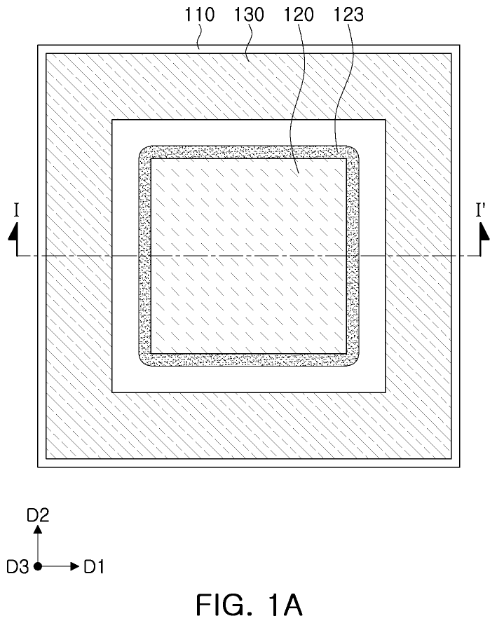

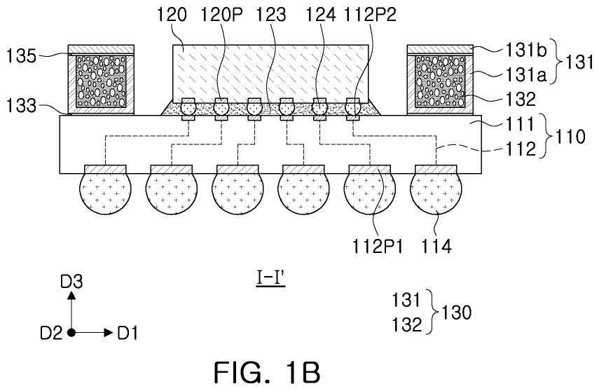

FIG. 1A is a plan view illustrating a semiconductor package 100A according to an example embodiment, and FIG. 1B is a cross-sectional view taken along line I-I′ of FIG. 1A.

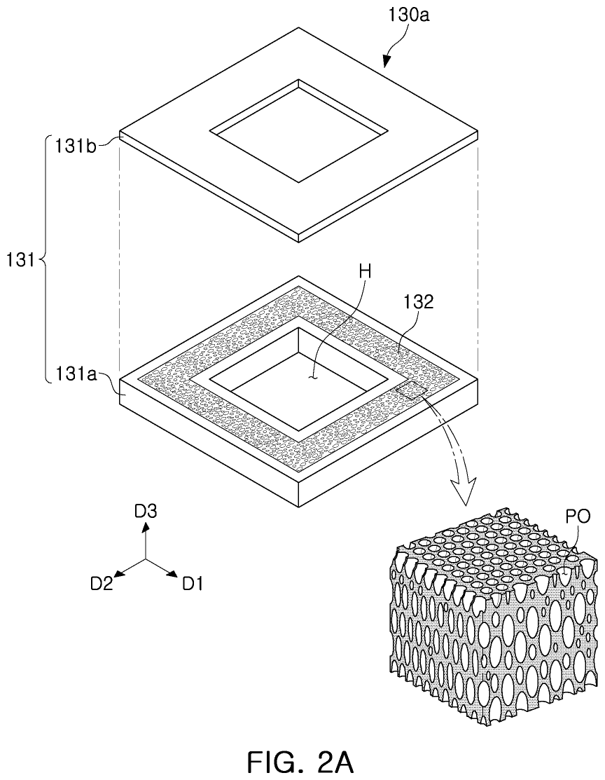

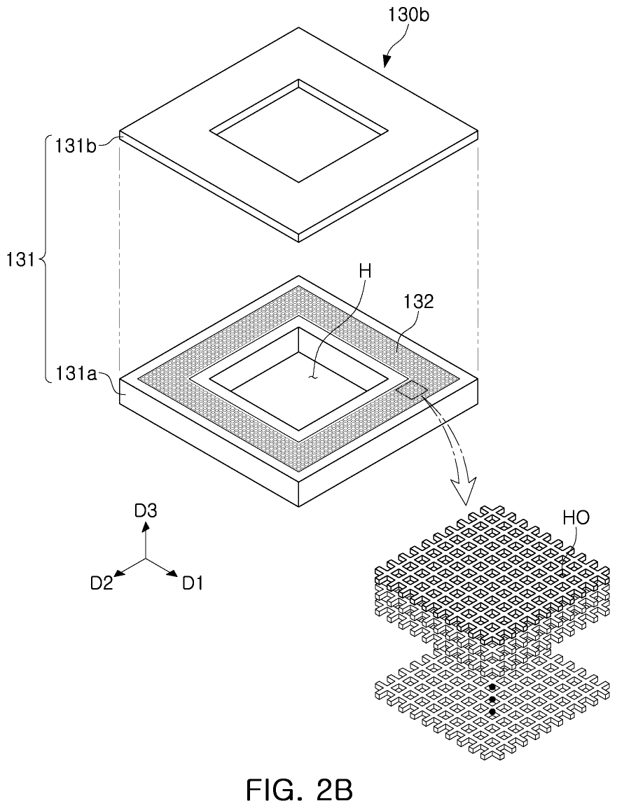

FIGS. 2A and 2B are perspective views of stiffeners 130a and 130b applicable to example embodiments.

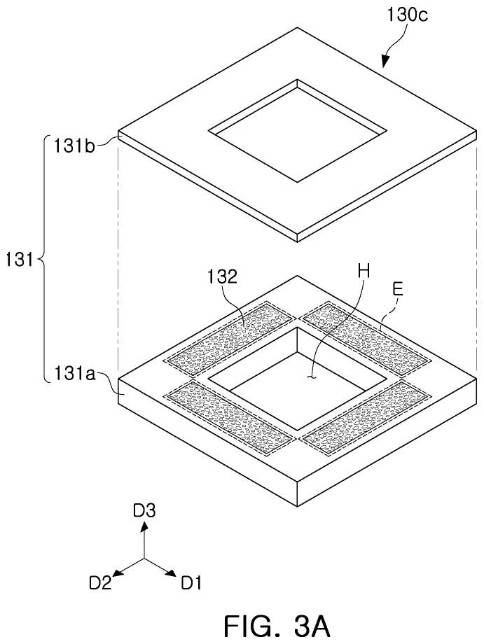

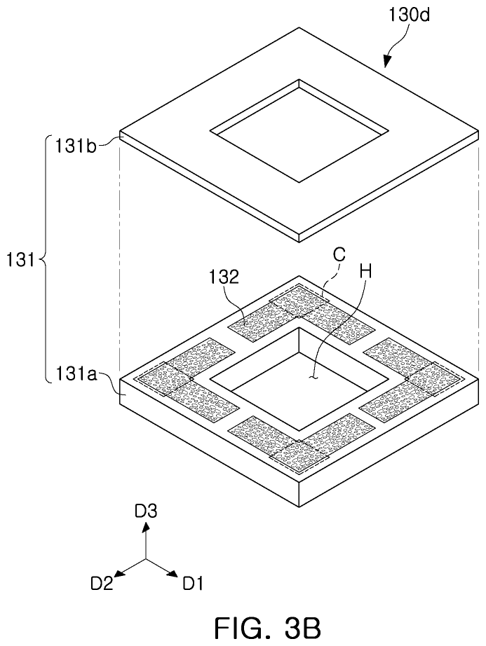

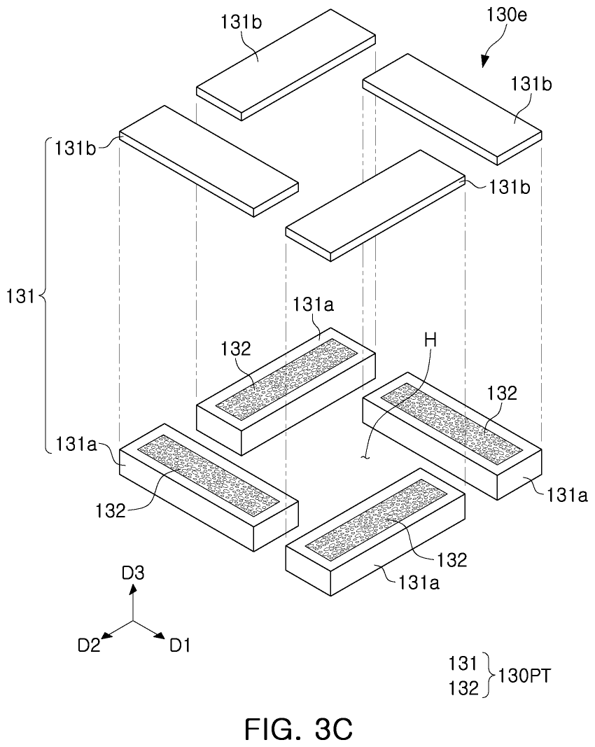

FIGS. 3A to 3C are perspective views of stiffeners 130c, 130d, and 130e according to some example embodiments.

Referring to FIGS. 1A, 1B, 2A, and 2B, a semiconductor package 100A according to an example embodiment may include a substrate 110, at least one semiconductor chip 120, and a stiffener 130.

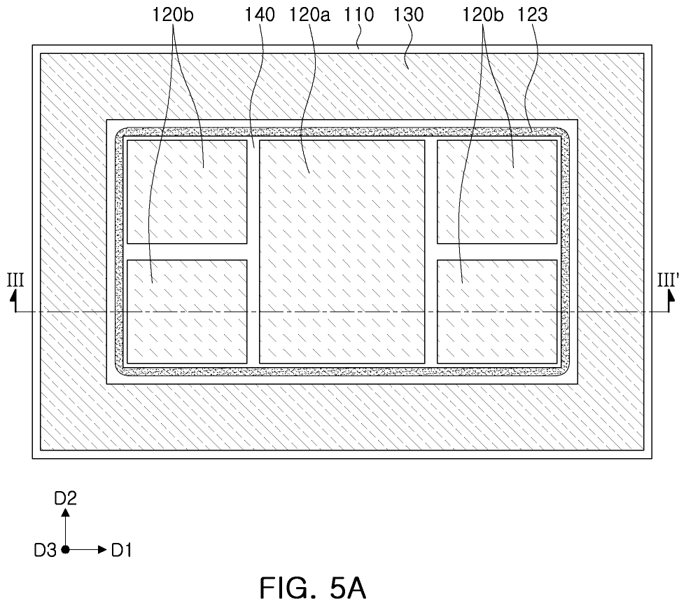

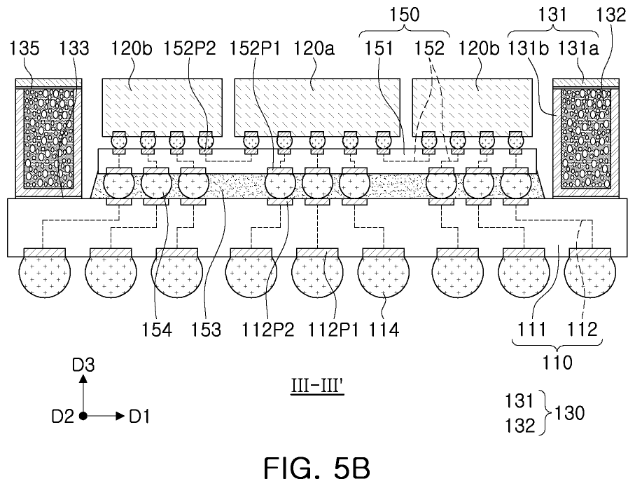

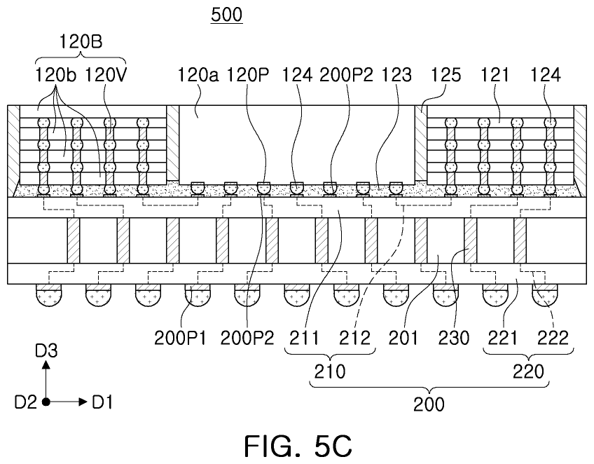

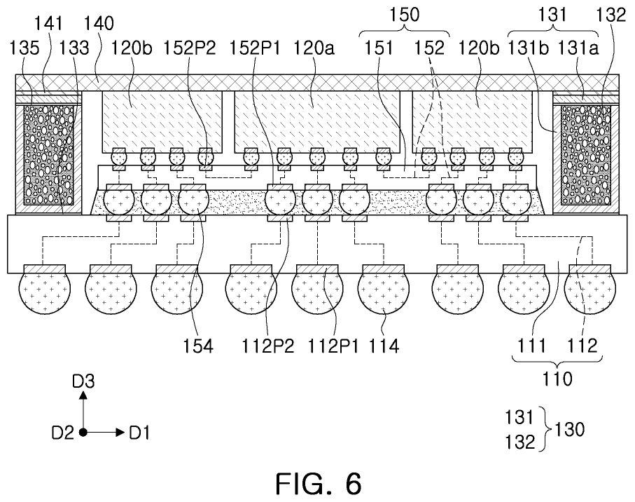

The substrate 110 may be a support substrate on which the semiconductor chip 120 and the stiffener 130 are mounted, and may include an insulating layer 111 and an interconnection 112. The substrate 110 may be a substrate for a semiconductor package and may include or may be a printed circuit board (PCB), a ceramic substrate, a glass substrate, a tape interconnection board, and the like. The substrate 110 may be a large-area substrate on which the semiconductor chip 120 or an interposer is mounted. As shown in the example embodiments of FIGS. 5A to 6, a semiconductor chip 120 may be mounted on the interposer. For example, the substrate 110 may have a planar shape such as a square or a rectangle (e.g., in a plan view), and a minimum width of the substrate 110 may be 40 mm or more, but the present inventive concept is not limited thereto. According to an example embodiment, the substrate 110 may further include a solder resist layer, covering a lower pad 112P1 and an upper pad 112P2.

The insulating layer 111 may include or be formed of an insulating material, electrically and physically protecting the interconnection 112, for example, a thermosetting resin such as an epoxy resin, a thermoplastic resin such as polyimide, or an prepreg, Ajinomoto Build-up Film (ABF), or Frame Retardant 4 (FR4) including an inorganic filler or/and a glass fiber (or a glass cloth or a glass fabric).

The interconnection 112 may extend within the insulating layer 111 to electrically connect the lower pad 112P1 and the upper pad 112P2. The interconnection 112 may include a conductive pattern (not illustrated) and a conductive via (not illustrated), forming an electrical connection path. The interconnection 112 may include an alloy of at least one metal or two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), tungsten (W), and iron (Fe).

As used herein, components described as being “electrically connected” are configured such that an electrical signal can be transferred from one component to the other (although such electrical signal may be attenuated in strength as it transferred and may be selectively transferred).

External connection bumps 114 may be disposed on a lower surface of the substrate 110. The external connection bumps 114 may electrically connect the semiconductor package 100A to external devices such as a module substrate and/or a main board. The external connection bumps 114 may include a solder ball and/or a conductive pillar. For example, the external connection bumps 114 may be solder balls or conductive pillars. The external connection bumps 114 may have a flip-chip connection structure having a grid array such as a pin grid array, a ball grid array, or a land grid array. The external connection bumps 114 may be electrically connected to lower pads 112P1 of the substrate 110.

As used herein, the singular forms “a”, “an” and “the” are intended to include the plural forms as well, unless the context clearly indicates otherwise. As used herein, the term “and/or” includes any and all combinations of one or more of the associated listed items and may be abbreviated as “/”.

The semiconductor chip 120 may be disposed on the substrate 110, and may be electrically connected to the interconnection 112 of the substrate 110 through connection bumps 124. The connection bumps 124 may electrically connect a connection pad 120P of the semiconductor chip 120 and the upper pad 112P2 of the substrate 110 to each other. For example, the connection bumps 124 may electrically connect connection pads 120P of the semiconductor chip 120 to the upper pads 112P2 of the substrate 110 respectively The connection bumps 124 may include or be formed of tin (Sn), indium (In), bismuth (Bi), antimony (Sb), copper (Cu), silver (Ag), zinc (Zn), lead (Pb), and/or alloys thereof (for example, Sn—Ag—Cu).

The semiconductor chip 120 may be an IC chip having an integrated circuit (IC) formed on a wafer. The semiconductor chip 120 may include or may be, for example, a logic chip such as a central processor (CPU), a graphics processor (GPU), a field programmable gate array (FPGA), a digital signal processor, a cryptographic processor, a microprocessor, a microcontroller, and an analog-to-digital converter, or an application-specific IC (ASIC), or memory chips such as a volatile memory such as dynamic RAM (DRAM) or static RAM (SRAM), and a non-volatile memory such as phase change RAM (PRAM), magnetic RAM (MRAM), resistive RAM (RRAM), or flash memory.

The semiconductor chip 120 may be a large-sized chip, mounted on the substrate 110 having a large area, e.g., in a plan view. For example, a minimum width of the semiconductor chip 120, e.g., in a horizontal direction, may be 20 mm or more, but the present inventive concept is not limited thereto. An underfill layer 123, surrounding connection bumps 124, may be disposed between the semiconductor chip 120 and the substrate 110. The underfill layer 123 may include or be formed of an insulating material such as an epoxy resin.

The stiffener 130 may be disposed on the substrate 110, and may include a body portion 131 and a thermally conductive portion 132. The stiffener 130 may be attached onto the substrate 110 by a first adhesive layer 133. The stiffener 130 may extend along a circumference of the substrate 110, for example, to have a rectangular shape. The stiffener 130 may be described herein as a stiffening frame or a stiffening support block. The stiffener 130 may be disposed around the semiconductor chip 120 or an interposer 150 (see the example embodiment of FIGS. 5A and 5B). For example, the semiconductor chip 120 may be disposed in an accommodation hole H formed in a central portion of the stiffener 130.

The body portion 131 may have an arrangement space for the thermally conductive portion 132. For example, the arrangement space may be a space in which the thermally conductive portion 132 is disposed. For example, the body portion 131 may include a lower body 131a, providing a sidewall and a bottom of a cavity, and an upper body 131b, covering (e.g., vertically overlapping) the lower body 131a and the thermally conductive portion 132 (e.g., disposed in the cavity). The body portion 131 may therefore be a hollow structure, for example, having a rectangular (e.g., square) ring shape. The upper body 131b may be attached/bonded to the lower body 131a and/or the thermally conductive portion 132 by a second adhesive layer 135. Each of the first adhesive layer 133 and the second adhesive layer 135 may include or be formed of a thermally conductive adhesive tape, a thermally-conductive grease, or a thermally conductive adhesive.

The thermally conductive portion 132 may be disposed within the body portion 131. For example, the thermally conductive portion 132 may be enclosed by the body portion 131. In some example embodiments, the thermally conductive portion 132 (which may be referred to as a “porous thermally conductive portion”) may be porous to reduce a weight of the semiconductor package 100A. The thermally conductive portion 132 may be, for example, a porous molded body (see FIG. 2A) using a casting method, a powder sintering method, or the like, or a mesh-type plate (see FIG. 2B). As illustrated in FIG. 2A, in a stiffener 130a according to an example embodiment, a thermally conductive portion 132 may be a porous molded body in which a plurality of pores PO are formed. For example, the thermally conductive portion 132 may be a porous molded body formed of metal thereby being a porous metal molded body. As illustrated in FIG. 2B, in a stiffener 130b according to an example embodiment, a thermally conductive portion 132 may be a mesh-type plate in which a plurality of holes HO are formed. In some example embodiments, the thermally conductive portion 132 may include or be formed of a plurality of mesh-shaped plates stacked within the body portion 131, e.g., the thermally conductive portion 132 may be formed of a plurality of mesh-type metal plates formed of metal and stacked in the cavity of the body portion 131, but the present inventive concept is not limited thereto.

The body portion 131 and the thermally conductive portion 132 may be modified to have various forms other than those illustrated in FIGS. 2A and 2B. For example, in a stiffener 130c according to the modification illustrated in FIG. 3A, a body portion 131 may have a square ring shape having an accommodation hole H formed in a central portion thereof, and the thermally conductive portion 132 may be disposed sides (E) of the body portion 131. For example, the thermally conductive portion 132 may be formed of a plurality of bars discretely disposed within the body portion 131. In a stiffener 130d according to the modification illustrated in FIG. 3B, a body portion 131 may have a square ring shape having an accommodation hole H formed in a central portion thereof, and a thermally conductive portion 132 may extend in a state of being bent to pass corners C of the body portion 131. For example, the thermally conductive portion 132 may be formed of a plurality of L-shape sub-portions discretely disposed within the body portion 131. The stiffener 130e according to the modification illustrated in FIG. 3C may include a plurality of stiffener portions 130 PT. Each of the plurality of stiffener portions 130 PT may include a body portion 131 and a thermally conductive portion 132. The plurality of stiffener portions 130 PT may be spaced apart from each other, e.g., in a horizontal direction, around an accommodation hole H. The stiffener 130 may be modified in various forms other than those illustrated in FIGS. 2A to 3C.

In example embodiments according to the present inventive concept, the body portion 131 and the thermally conductive portion 132 have different physical properties, thereby controlling warpage of a semiconductor package, improving heat dissipation characteristics, and improving reliability of the semiconductor package. For example, the body portion 131 may include a first material having a tensile strength greater than that of a material included in the thermally conductive portion 132. The thermally conductive portion 132 may include a second material having a coefficient of thermal expansion and a thermal conductivity greater than those of a material included in the body portion 131. Each of the first material and the second material may include or may be a metal such as copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), tungsten (W), iron (Fe), or an alloy of at least one of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), tungsten (W), and iron (Fe), but the present inventive concept is limited thereto. For example, the body portion 131 (“first material”) may include or be formed of iron (Fe) or an alloy of iron (Fe) (for example, stainless steel (SUS)), and the thermally conductive portion 132 may include or be formed of copper (Cu) or an alloy of copper (Cu). In some example embodiments, each of the first material and the second material may include or may be another material (for example, a polymer, a ceramic, and the like), satisfying physical properties described below, in addition to or as an alternative to the above-described metals.

A first coefficient of thermal expansion of the body portion 131 may be less than a second coefficient of thermal expansion of the thermally conductive portion 132. The first coefficient of thermal expansion of the body portion 131 may be at a similar level to that of the substrate 110. Here, the “coefficient of thermal expansion of the substrate 110” may refer to physical properties comprehensively determined by a type, distribution, and form of different materials included in the substrate 110. In addition, the “similar level” may mean that the first coefficient of thermal expansion is less than the second coefficient of thermal expansion and is maximally close to the thermal expansion of the substrate 110 such that the first coefficient of thermal expansion compensates for a difference between the second coefficient of thermal expansion of the thermally conductive portion 132 and the coefficient of thermal expansion of the substrate 110. For example, the “similar level” does not limit a relationship between the coefficient of thermal expansion of the substrate 110 and the first coefficient of thermal expansion to a specific numerical range. For example, the first coefficient of the thermal expansion of the body portion 131 may be greater than the coefficient of thermal expansion of the substrate 110. For example, the second coefficient of the thermal expansion of the thermally conductive portion 132 may be greater than the coefficient of thermal expansion of the substrate 110. For example, a difference between the first coefficient of the thermal expansion and the second coefficient of thermal expansion may be greater than a difference between the first coefficient of the thermal expansion of the body portion 131 and the coefficient of thermal expansion of the substrate 110.

The coefficient of thermal expansion of the substrate 110 may be in a range of about 5 ppm/° C. to about 15 ppm/° C., for example, about 5 ppm/° C. to about 12 ppm/° C., about 7 ppm/° C. to about 12 ppm/° C., or about 8 ppm/° C. to about 11 ppm/° C. The first coefficient of thermal expansion of the body portion 131 may be in a range of about 5 ppm/° C. to about 15 ppm/° C., for example, about 5 ppm/° C. to about 13 ppm/° C., about 8 ppm/° C. to about 13 ppm/° C., or about 9 ppm/° C. to about 12 ppm/° C. The second coefficient of thermal expansion of the thermally conductive portion 132 may be in a range of about 10 ppm/° C. to about 20 ppm/° C., for example, about 14 ppm/° C. to about 20 ppm/° C., about 14 ppm/° C. to about 18 ppm/° C., or about 15 ppm/° C. to about 18 ppm/° C. However, the coefficient of thermal expansion of each of the substrate 110, the body portion 131, and the thermally conductive portion 132 are not limited to the above-described numerical ranges.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

In order to form a coefficient of thermal expansion of the stiffener 130 at a level similar to that of the substrate 110, a volume of the body portion 131 may have a range of about 10% or more and about 50% or less of a total volume of the stiffener 130. When the volume of the body portion 131 is less than about 10%, the stiffener 130 may have an increased coefficient of thermal expansion and a reduced effect of controlling warpage. When the volume of the body portion 131 is greater than about 50%, a volume of the thermally conductive portion 132 may be relatively reduced, and heat dissipation characteristics of a package may be degraded.

The body portion 131 may have relatively high strength (indicating at least one of compressive strength, tensile strength, and warpage strength), thereby controlling/preventing warpage of the package. For example, a first tensile strength of the body portion 131 may be greater than a second tensile strength of the thermally conductive portion 132. The first tensile strength of the body portion 131 may be in a range of about 370 MPa to about 470 MPa, for example, about 390 MPa to about 450 MPa, or about 400 MPa to about 450 MPa. The second tensile strength of the thermally conductive portion 132 may be in a range of about 340 MPa to about 440 MPa, for example, about 360 MPa to about 420 MPa, or about 380 MPa to about 400 MPa. However, the tensile strengths of the body portion 131 and the thermally conductive portion 132 is not limited to the above-described numerical ranges.

The thermally conductive portion 132 may have relatively high thermal conductivity, thereby improving heat dissipation characteristics of the package. A first thermal conductivity of the body portion 131 may be less than a second thermal conductivity of the thermally conductive portion 132. The first thermal conductivity of the body portion 131 may be in a range of about 10 W/m·K to about 30 W/m·K, for example, about 10 W/m·K to about 28 W/m·K, about 12 W/m·K K to about 28 W/m·K, or about 13 W/m·K to about 27 W/m·K. The second thermal conductivity of the thermally conductive portion 132 may be in a range of about 350 W/m·K to about 450 W/m·K, for example, about 380 W/m·K to about 450 W/m·K, about 380 W/m·K K to about 430 W/m·K, or about 390 W/m·K to about 430 W/m·K. However, the thermal conductivities of the body portion 131 and the thermally conductive portion 132 are not limited to the above-described numerical ranges.

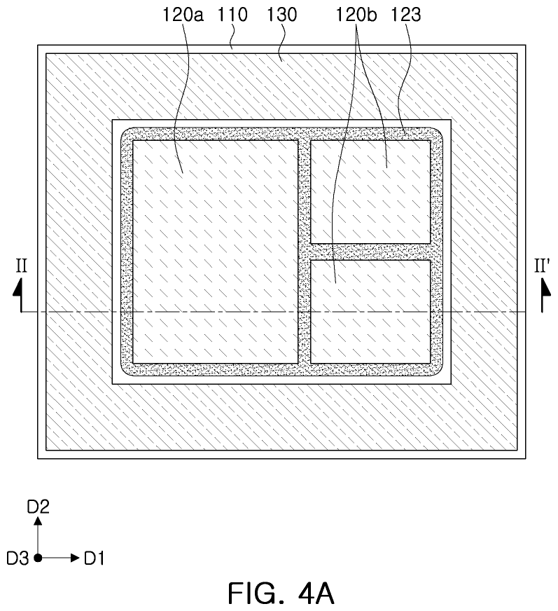

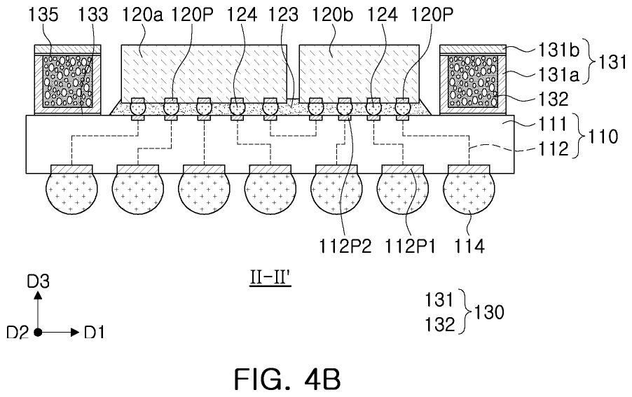

FIG. 4A is a plan view of a semiconductor package 100B according to an example embodiment, and FIG. 4B is a cross-sectional view taken along line II-II′ of FIG. 4A.

Referring to FIGS. 4A and 4B, the semiconductor package 100B according to an example embodiment may have features the same as or similar to those described with reference to FIGS. 1A to 3C, except that a plurality of semiconductor chips 120a and 120b are disposed on a substrate 110. For example, the plurality of semiconductor chips 120a and 120b may be disposed in an accommodation hole H formed in a central portion of a stiffener 130 and surrounded by the stiffener 130 on the substrate 110. The semiconductor package 100B may include a first semiconductor chip 120a and at least one second semiconductor chip 120b. The first semiconductor chip 120a and the second semiconductor chip 120b may be electrically connected to each other through an interconnection 112 of the substrate 110.

The first semiconductor chip 120a and the second semiconductor chip 120b may include or may be different types of semiconductor chips from each other. For example, the first semiconductor chip 120a may include or may be a logic chip such as a CPU, a GPU, a FPGA, a digital signal processor, a cryptographic processor, a microprocessor, a microcontroller, an analog-digital converter, or an ASIC, and the second semiconductor chip 120b may include or may be a memory chip such as DRAM, SRAM, PRAM, ReRAM, FeRAM, MRAM, or flash memory. In some example embodiments, the second semiconductor chip 120b may be provided as a high-performance memory device such as a high bandwidth memory (HBM) or a hybrid memory cube (HMC).

In some example embodiments, the first semiconductor chip 120a and the second semiconductor chip 120b may include or may be the same type of semiconductor chip. For example, both the first semiconductor chip 120a and the second semiconductor chip 120b may include or may be a logic chip or a memory chip.

FIG. 5A is a plan view of a semiconductor package 100C according to an example embodiment, FIG. 5B is a cross-sectional view taken along line III-III′ of FIG. 5A, and FIG. 5C is a cross-sectional view of an interposer package 500 according to an example embodiment.

Referring to FIGS. 5A and 5B, the semiconductor package 100C according to an example embodiment may have features the same as or similar to those described with reference to FIGS. 1A to 4B, except that an interposer 150, electrically connecting at least one semiconductor chip 120a or 120b and a substrate 110 to each other, is further included.

In an example embodiment, a stiffener 130 may be disposed on the substrate 110 to be spaced apart from the interposer 150, e.g., in a horizontal direction. The stiffener 130 may extend on the substrate 110 to surround a side surface of the interposer 150. For example, the interposer 150 may be disposed in an accommodation hole formed in a central portion of the stiffener 130 on the substrate 110.

The interposer 150 according to an example embodiment may be a PCB, a ceramic substrate, or a tape substrate for interconnecting a first semiconductor chip 120a, a second semiconductor chip 120b, and the substrate 110. The interposer 150 may include a dielectric layer 151 and an interconnection 152. The dielectric layer 151 may include or be formed of an insulating material, for example, a thermosetting resin such as an epoxy resin, a thermoplastic resin such as polyimide, or a prepreg, ABF, or FR4 including an inorganic filler or/and a glass fiber (or a glass cloth or a glass fabric). The interconnection 152 may extend within the dielectric layer 151 to electrically connect a lower pad 152P1 and am upper pad 152P2 to each other. The interconnection 152 may include a conductive pattern (not illustrated) and a conductive via (not illustrated), forming an electrical connection path. The interconnection 152 may be formed of an alloy of at least one metal or two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), tungsten (W), and iron (Fe). The interconnection 152 of the interposer 150 may be electrically connected to an interconnection 112 of the substrate 110 through connection bumps 154. An underfill layer 153, surrounding the connection bumps 154, may be disposed between the interposer 150 and the substrate 110.

In some example embodiments, the interposer 150 may be a silicon interposer substrate including a through-silicon via (TSV). In this case, the dielectric layer 151 may include or be formed of silicon oxide, silicon nitride, or the like. Hereinafter, the interposer package 500, applicable to example embodiments, will be described with reference to FIG. 5C. It can be understood that the interposer package 500 illustrated in FIG. 5C is applied instead of the semiconductor chips 120a and 120b and the interposer 150 illustrated in FIG. 5B.

Referring to FIG. 5C, the interposer package 500 may include a first semiconductor chip 120a, at least one chip structure 120B, and an interposer substrate 200.

The first semiconductor chip 120a may include or may be a logic chip such as a CPU, a GPU, a FPGA, a digital signal processor, a cryptographic processor, a microprocessor, a microcontroller, an analog-digital converter, or an ASIC.

At least one chip structure 120B may include a plurality of second semiconductor chips 120b vertically stacked. The plurality of second semiconductor chips 120b may be electrically connected to each other through-vias 120V, passing through at least a portion of the second semiconductor chips 120b. An adhesive film layer 121, surrounding the connection bumps 124 may be disposed between the plurality of second semiconductor chips 120b. The adhesive film layer 121 may include or be formed of a non-conductive film (NCF). Each semiconductor chip 120b of the plurality of second semiconductor chips 120b may include or may be a memory chip such as DRAM, SRAM, PRAM, ReRAM, FeRAM, MRAM, or flash memory. The chip structure 120B may further include a buffer chip (not illustrated) for the plurality of second semiconductor chips 120b. The chip structure 120B may be, for example, a high-performance memory device such as an HBM or HMC.

The interposer substrate 200 may include a semiconductor substrate 201, an upper circuit layer 210, a lower circuit layer 220, and through-vias 230. The interposer substrate 200 may include a lower pad 200P1 and an upper pad 200P2. The lower pad 200P1 and the upper pad 200P2 may include or be formed of, for example, at least one metal, among aluminum (Al), copper (Cu), nickel (Ni), tungsten (W), platinum (Pt), and gold (Au), but the present inventive concept is not limited thereto.

The semiconductor substrate 201 may include or be formed of semiconductor elements such as silicon and germanium, or compound semiconductors such as silicon carbide (SiC), gallium arsenide (GaAs), indium arsenide (InAs), and indium phosphide (InP).

The upper circuit layer 210 may be disposed on an upper portion (e.g., on a top/upper surface) of the semiconductor substrate 201, and may include an interlayer insulating layer 211 and an upper connection interconnection 212. The interlayer insulating layer 211 may include or be formed of silicon oxide or silicon nitride. The upper connection interconnection 212 may electrically interconnect the first semiconductor chip 120a and the chip structure 120B or electrically connect the first semiconductor chip 120a and the chip structure 120B to the through-vias 230.

The lower circuit layer 220 is disposed on a lower portion (e.g., on a bottom/lower surface) of the semiconductor substrate 201, and may include an interlayer insulating layer 221 and a lower connection interconnection 222. The interlayer insulating layer 221 and the lower connection interconnection 222 of the lower circuit layer 220 may respectively include materials the same as or similar to those of the interlayer insulating layer 211 and the upper connection interconnection 212 of the upper circuit layer 210 described above.

The through-vias 230 may be through-silicon vias (TSVs), passing through the semiconductor substrate 201 in a vertical direction D3. The through-vias 230 may provide an electrical path electrically connecting a lower pad 200P1 and upper pads 200P2 to each other. The through-via 230 may include a conductive plug and a barrier film, surrounding the conductive plug. The conductive plug may include or be formed of a metal such as tungsten (W), titanium (Ti), aluminum (Al), or copper (Cu). The conductive plug may be formed using a plating process, a PVD process, or a CVD process. The barrier film may include an insulating barrier film and/or a conductive barrier film. The insulating barrier film may be formed of an oxide film, a nitride film, a carbide film, a polymer, or combinations thereof. The conductive barrier film may include, for example, a metal compound such as tungsten nitride (WN), titanium nitride (TiN), or tantalum nitride (TaN). The barrier film may be formed using a PVD process or a CVD process.

In addition, an encapsulant 125 for encapsulating at least a portion of each of the first semiconductor chip 120a and the chip structure 120B may be disposed on the interposer substrate 200. For example, the encapsulant 125 may cover and contact a side wall of each of the first semiconductor chip 120a and the chip structure 120B. The encapsulant 125 may include or be formed of, for example, an epoxy molding compound (EMC), but the present inventive concept is not limited thereto.

FIG. 6 is a cross-sectional view of a semiconductor package 100D according to an example embodiment of the present inventive concept.

Referring to FIG. 6, the semiconductor package 100D according to an example embodiment may have features the same as or similar to those described with reference to FIGS. 1A to 5C, except that a stiffener 130 and a heat dissipation plate 140 on semiconductor chips 120a and 120b are further included. The heat dissipation plate 140 may control/prevent warpage of the semiconductor package 100D, and may externally dissipate heat transferred from a first semiconductor chip 120a, a second semiconductor chip 120b, and the stiffener 130. The heat dissipation plate 140 may include or be formed of a material having excellent thermal conductivity, for example, aluminum (Al), gold (Au), silver (Ag), copper (Cu), iron (Fe), graphite, or graphene. The heat dissipation plate 140 may have a plate shape. For example, the heat dissipation plate 140 may be a thin flat plate extending in a horizontal direction. However, the present inventive concept is not limited thereto. The heat dissipation plate 140 may be attached to the stiffener 130 by an electrically insulating and thermally conductive layer 141. The electrically insulating and thermally conductive layer 141 may include or be formed of a thermal interface material (TIM) such as a thermally conductive adhesive tape, thermally conductive grease, or thermally conductive adhesive. In some example embodiments, the electrically insulating and thermally conductive layer 141 may also be disposed between the heat dissipation plate 140 and the semiconductor chips 120a and 120b.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

According to example embodiments of the present inventive concept, a stiffener capable of resolving/improving a warpage issue and improving heat dissipation characteristics may be introduced, thereby providing a semiconductor package having improved reliability.

While example embodiments have been shown and described above, it will be apparent to those skilled in the art that modifications and variations could be made without departing from the scope of the present inventive concept as defined by the appended claims.

What is claimed is:

1. A semiconductor package comprising:
a substrate including a first interconnection;
an interposer disposed on the substrate, the interposer including a second interconnection electrically connected to the first interconnection;
first and second semiconductor chips disposed on the interposer, the first and second semiconductor chips electrically connected to each other through the second interconnection; and
a stiffener disposed on the substrate to be spaced apart from the interposer, the stiffener including a body portion having a cavity, and a porous thermally conductive portion within the cavity,
wherein the body portion includes a first material having a first coefficient of thermal expansion, and
the porous thermally conductive portion includes a second material having a second coefficient of thermal expansion, greater than the first coefficient of thermal expansion.

2. The semiconductor package of claim 1, wherein
the substrate further includes an insulating layer in which the first interconnection extends, and
the second coefficient of thermal expansion is greater than a coefficient of thermal expansion of the substrate.

3. The semiconductor package of claim 2, wherein
the coefficient of thermal expansion of the substrate is in a range of about 5 ppm/° C. to about 15 ppm/° C., and
the first coefficient of thermal expansion is in a range of about 5 ppm/° C. to about 15 ppm/° C.

4. The semiconductor package of claim 2, wherein the second coefficient of thermal expansion is in a range of about 10 ppm/° C. to about 20 ppm/° C.

5. The semiconductor package of claim 1, wherein a first thermal conductivity of the first material is less than a second thermal conductivity of the second material.

6. The semiconductor package of claim 5, wherein
the first thermal conductivity is in a range of about 10 W/m·K to about 30 W/m·K, and
the second thermal conductivity is in a range of about 350 W/m·K to about 450 W/m·K.

7. The semiconductor package of claim 1, wherein a first tensile strength of the first material is greater than a second tensile strength of the second material.

8. The semiconductor package of claim 7, wherein
the first tensile strength is in a range of about 370 MPa to about 470 MPa, and
the second tensile strength is in a range of about 340 MPa to about 440 MPa.

9. The semiconductor package of claim 1, wherein
the first material includes iron (Fe) or an alloy of iron (Fe), and
the second material includes copper (Cu) or an alloy of copper (Cu).

10. The semiconductor package of claim 1, wherein the body portion includes a lower body, providing a sidewall and a bottom of the cavity, and an upper body, covering the cavity.

11. The semiconductor package of claim 10, further comprising:
an adhesive layer disposed between the lower body and the upper body.

12. The semiconductor package of claim 1, wherein the porous thermally conductive portion is a porous metal molded body.

13. The semiconductor package of claim 1, wherein the porous thermally conductive portion is formed of a plurality of mesh-type metal plates.

14. The semiconductor package of claim 1, wherein the stiffener extends on the substrate to surround a side surface of the interposer.

15. The semiconductor package of claim 1, wherein a volume of the body portion is about 10% or more and about 50% or less of a total volume of the stiffener.

16. A semiconductor package comprising:
a substrate;
at least one semiconductor chip disposed on the substrate; and
a stiffener disposed on the substrate, the stiffener including a body portion having a cavity, and a porous thermally conductive portion within the cavity,
wherein the porous thermally conductive portion includes a porous molded body or a mesh-type plate,
a tensile strength of the body portion is greater than a tensile strength of the porous thermally conductive portion, and
a thermal conductivity of the porous thermally conductive portion is greater than a thermal conductivity of the body portion.

17. The semiconductor package of claim 16, wherein the body portion includes a lower body, providing the cavity, and an upper body, bonded to the lower body.

18. The semiconductor package of claim 16, wherein the body portion includes stainless steel (SUS), and
the porous thermally conductive portion includes copper (Cu).

19. A semiconductor package comprising:
a substrate;
an interposer disposed on the substrate;
at least one semiconductor chip disposed on the interposer; and
a stiffener disposed on the substrate, the stiffener including a body portion having a cavity and a thermally conductive portion within the cavity,
wherein the body portion includes a lower body providing the cavity and an upper body covering the lower body and the thermally conductive portion, and
a first thermal conductivity of the body portion is less than a second thermal conductivity of the thermally conductive portion.

20. The semiconductor package of claim 19, wherein a first tensile strength of the body portion is greater than a second tensile strength of the thermally conductive portion.
